(19) United States
(12) Patent Application Publication
(10) Pub. No.: US 2013/0059168 A1
(43) Pub. Date: Mar. 7, 2013

(54) Magnetoresistance Device

(71) Applicants: Taiebeh Tahmasebi, Singapore (SG); Seidikkurippu Nellainayagam Piramanayagam, Singapore (SG); Rachid Sbiaa, Singapore (SG)

(72) Inventors: Taiebeh Tahmasebi, Singapore (SG); Seidikkurippu Nellainayagam Piramanayagam, Singapore (SG); Rachid Sbiaa, Singapore (SG)

(73) Assignee: Agency fo Science, Technology and Research

(21) Appl. No.: 13/599,169

(22) Filed: Aug. 30, 2012

Related U.S. Application Data
(60) Provisional application No. 61/529,269, filed on Aug. 31, 2011.

(51) Int. Cl. G11C 7/00

(52) U.S. Cl. 428/811.2

(57) ABSTRACT

A magnetoresistance device is provided. The magnetoresistance device includes a hard magnetic layer, and a soft magnetic layer having a multi-layer stack structure. The multi-layer stack structure has a first layer of a first material and a second layer of a second material. The first material includes cobalt iron boron and the second material includes palladium or platinum.

This application claims the benefit of U.S. Provisional Application No. 61/529,269, filed Aug. 31, 2011.

### FIELD OF THE INVENTIONS

Various embodiments relate generally to a magnetoresistance device.

### BACKGROUND OF THE INVENTIONS

Magnetic random access memory (MRAM) is emerging as an alternative to conventional semiconductor memories. Compared to static random access memory (SRAM) and dynamic random access memory (DRAM), the MRAM has an advantage of non-volatility. Compared to flash memory used for storage of information, the MRAM has an advantage of endurance. MRAM devices may have advantages of non-volatility, practically infinite write endurance, and short read and write times. In order to compete with flash memory, it is desirable to increase the density of the MRAM cells in a chip, which may involve keeping the MRAM cells as small as possible. In order to compete with SRAM and DRAM, it is desirable to increase the speed of operation without compromising the density. Further, it is also desirable to achieve low current switching without compromising thermal stability.

Memory elements for MRAMs may include giant magnetoresistive (GMR) spin valves (SV). The GMR-SV may include two ferromagnetic layer separated by a non-magnetic metallic spacer layer. However, a larger magnetoresistance (MR) signal has been found in Magnetic Tunnel Junction (MTJ) devices where the tunneling magnetoresistance (TMR) occurs due to the use of an insulator layer between the ferromagnetic layers instead of a metallic spacer layer. The MTJ devices can be used in MRAM devices, where the difference in the resistance between two remanent states can be used to represent digital bits 0 and 1.

Spin-torque transfer based MRAMs (STT-MRAMs) can be scalable to very small sizes (e.g. 5 nm of FePt material, based on the thermal stability considerations only) as compared to field-switchable MRAM devices. However, the smallest possible cell size is not only limited by thermal stability, but also by the writability. Devices with FePt may require a large write current required for the write operation. Moreover, two geometries, one with magnetization in plane and another with magnetization out-of-plane (perpendicular), are being investigated.

Magnetic layers with in-plane and perpendicular anisotropy can be used in memory element structures. Magnetic layers with perpendicular magnetic anisotropy (PMA) may have several advantages over conventional in-plane magnetized layers such as improved thermal stability, scalability and low spin transfer torque (STT) switching current for nanoscale Spin Transfer Torque MRAM (STT-MRAM). Therefore, magnetic layers with PMA may be used for realizing a practical and scalable STT-MRAM.

Materials with high PMA such as cobalt (Co)/palladium (Pd) or cobalt (Co)/platinum (Pt) magnetic multilayers and also iron palladium (FePt) or cobalt platinum (CoPt) alloys can be considered for forming magnetic layers with PMA. The alloy films with PMA such as L1₀-FePt, L1₀-CoPt and ordered Co₃Pt may exhibit extremely large magnetocrystalline anisotropy (up to 7×10⁷ erg/cm³ for FePt) due to the spin-orbit coupling of platinum, and the strong hybridization between the Pt 5d and Co or Fe 3d electronic states. The easy axis of chemically ordered L1₀-FePt and L1₀-CoPt ferromagnetic materials which lies along (001) crystal orientation can be used in MTJ devices to achieve a better thermal stability due to the larger anisotropy constant, and therefore, may allow potential scaling of the MTJ devices down to 5 nm.

The Co/Pd, Co/Pt, Co/nickel (Ni), etc magnetic multilayers have been widely investigated due to their wide applications and relative ease in achieving perpendicular magnetic anisotropy (PMA). Although Co/Pd, Co/Pt magnetic multilayers and FePt alloy possess desired properties for the hard layers of the MRAM devices (that retain their magnetization direction), their use as the soft layer is difficult. Devices based on Co/Pd multilayers or FePt layers have a high anisotropy constant and hence they can retain their magnetization in a stable manner. However, as the writing current is also proportional to the anisotropy constant, such materials need a high current to switch, posing a limitation in the transistor size (or the density of cells) or in the operating speed.

### SUMMARY

According to one embodiment, a magnetoresistance device is provided. The magnetoresistance device includes a hard magnetic layer, and a soft magnetic layer having a multi-layer stack structure. The multi-layer stack structure has a first layer of a first material and a second layer of a second material. The first material includes cobalt iron boron and the second material includes palladium or platinum.

According to another embodiment, a magnetoresistance device is provided. The magnetoresistance device includes a hard magnetic layer, and a soft magnetic layer having a multi-layer stack structure. The multi-layer stack structure has a first layer of a first material and a second layer of a second material. The first material includes a cobalt based magnetic material.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a three-dimensional view of a magnetoresistance device according to one embodiment.

FIG. 2 shows a schematic diagram of a multi-layer stack structure of a soft magnetic layer of a magnetoresistance device according to one embodiment.

FIG. 3 shows a three-dimensional view of a magnetoresistance device according to one embodiment.

FIG. 4 shows a schematic diagram of a magnetoresistance device according to one embodiment.

FIG. 5 shows a graph illustrating a hysteresis loop of a magnetoresistance device for different thicknesses of a seed layer structure according to one embodiment.

FIG. 6 shows a graph illustrating a magnetoresistance behavior of a magnetoresistance device for different thicknesses of a seed layer structure according to one embodiment.

FIG. 7 shows a graph illustrating a magnetoresistance behavior of a magnetoresistance device according to one embodiment

FIG. 8 shows a graph illustrating switching behavior of a conventional device.

FIG. 9 shows a switching field of a soft magnetic layer of a magnetoresistance device and magnetoresistance of the magnetoresistance device plotted against a size of the magnetoresistance device according to one embodiment.

### DETAILED DESCRIPTION OF THE INVENTIONS

Embodiments of a magnetoresistance device will be described in detail below with reference to the accompanying figures. It will be appreciated that the embodiments described below can be modified in various aspects without changing the essence of the invention.

In one embodiment, the magnetoresistance device may include a hard magnetic layer and a soft magnetic layer having a multi-layer stack structure. The multi-layer stack structure may have a first layer of a first material and a second layer of a second material. The first material may include cobalt iron boron and the second material may include palladium or platinum.

In another embodiment, the magnetoresistance device may include a hard magnetic layer, and a soft magnetic layer having a multi-layer stack structure. The multi-layer stack structure may have a first layer of a first material and a second layer of a second material. The first material may include a cobalt based magnetic material. The cobalt based magnetic material may have a formula Co—X—Y. In one embodiment, X may include iron, and Y may include boron or boron nitride. The second material may include platinum, palladium or nickel.

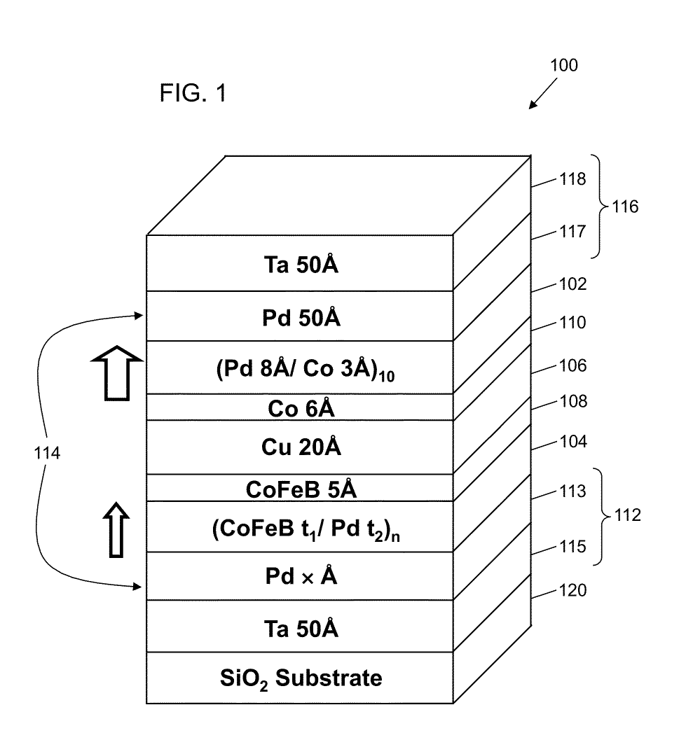

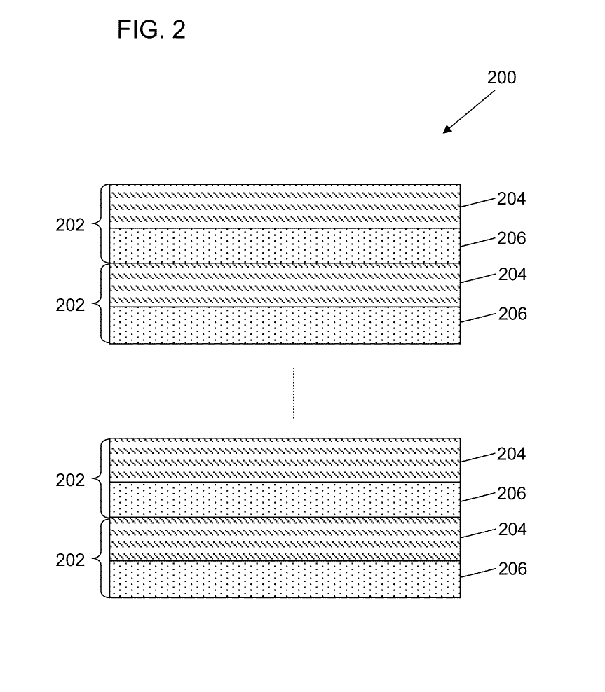

FIG. 1 shows a three-dimensional view of a magnetoresistance device 100 according to one embodiment. The magnetoresistance device 100 has a hard magnetic layer 102 and a soft magnetic layer 104. In one embodiment, the soft magnetic layer 104 has a multi-layer stack structure 200 as shown in FIG. 2. The multi-layer stack structure 200 has one or more stacks 202. The number of stacks 202 of the multi-layer stack structure 200 ranges from 2 to 20. The number of stacks 202 may affect the stability of the soft magnetic layer 104. When the number of stacks 202 is larger, the soft magnetic layer 104 is thicker and is more stable.

Each stack 202 has a first layer 204 of the first material and a second layer 206 of the second material. In one embodiment, the first material may include cobalt iron boron (CoFeB) and the second material may include palladium (Pd) or platinum (Pt). The multi-layer stack structure 200 may have an alternating arrangement of the first layer 204 of the first material and the second layer 206 of the second material. The soft magnetic layer 104 has a CoFeB/Pd or CoFeB/Pt multi-layer structure.

Cobalt iron boron, palladium and platinum have high anisotropy. Thus, using cobalt iron boron and palladium or platinum in the soft magnetic layer 104 can make the perpendicular magnetic anisotropy (PMA) in the soft magnetic layer 104 to be stronger. Therefore, the soft magnetic layer 104 may be more stable. As such, it may be possible to reduce the size of the magnetoresistance device 100 to e.g. below 40 nm. The magnetoresistance device 100 having a reduced size may be used for higher storage density.

A value of magnetization for the first layer 204 of the first material (e.g. the first layer 204 of cobalt iron boron) may be chosen to reduce a switching current and to improve the perpendicular magnetic anisotropy (PMA). The perpendicular magnetic anisotropy (PMA) of the soft magnetic layer 104 may be controlled for suitable thermal stability by using the thickness of the second layer 206 of the second material or by using seed layers.

The first layer 204 of cobalt iron boron may have optimized concentration of cobalt and iron. In one embodiment, the CoFeB composition may be Co₂₀Fe₆₀B₂₀. The switching current can be optimized by varying the composition of CoFeB.

In one embodiment, the first layer 204 of the first material and the second layer 206 of the second material may have the same thickness. In another embodiment, the first layer 204 of the first material and the second layer 206 of the second material may have different thicknesses. The first layer 204 of the first material may have a thickness ranging from about 0.25 nm to about 0.6 nm. The second layer 206 of the second material may have a thickness ranging from about 0.4 nm to about 1.2 nm.

Referring back to FIG. 1, the hard magnetic layer 102 may include any hard layer with perpendicular magnetic anisotropy (PMA). The hard magnetic layer 102 may include but is not limited to cobalt platinum (e.g. L1₀ CoPt) and iron platinum (e.g. L1₀ FePt). The hard magnetic layer 102 may also include a multi-layer stack structure. The multi-layer stack structure of the hard magnetic layer 102 may be similar to the multi-layer stack structure 200 of the soft magnetic layer 104. The multi-layer stack structure of the hard magnetic layer 102 may have a first layer of cobalt and a second layer of material. The first layer of cobalt and a second layer of material may be arranged in an alternating arrangement. The material used for the second layer may include but is not limited to platinum, palladium, iron palladium and nickel. The material used for the second layer may also include a combination of materials including but not limited to platinum, palladium, iron palladium and nickel.

In one embodiment, the multi-layer stack structure of the hard magnetic layer 102 may have ten stacks. Each stack may have a first layer of palladium and a second layer of cobalt. Each first layer of palladium may have a thickness ranging between about 5 Å to about 15 Å. Each second layer of cobalt may have a thickness ranging between about 5 Å to about 20 Å.

The magnetoresistance device 100 may also include a spacer layer 106 disposed between the hard magnetic layer 102 and the soft magnetic layer 104. In one embodiment, the spacer layer 106 may include copper. In another embodiment, the spacer layer 106 may include magnesium oxide (MgO), aluminum oxide (AlO) or alumina (Al₂O₃) for achieving higher tunneling magnetoresistance (TMR). In another embodiment, the spacer layer 106 may include stack of magnesium or magnesium oxide or aluminum oxide (AlₓO_{y}). The spacer layer 106 may have a thickness ranging between about 8 Å to about 20 Å.

The magnetoresistance device 100 may further include a first spin-polarizing layer structure 108 and a second spin-polarizing layer structure 110. The first spin-polarizing layer structure 108 is disposed between the spacer layer 106 and the soft magnetic layer 104. The second spin-polarizing layer structure 110 is disposed between the spacer layer 106 and the hard magnetic layer 102.

The first spin-polarizing layer structure 108 has one or more layers. The one or more layers of the first spin-polarizing layer structure 108 may be arranged in a stack. Each layer of the first spin-polarizing layer structure 108 may include but is not limited to cobalt iron boron (CoFeB), cobalt, iron and cobalt iron. Each layer of the first spin-polarizing layer structure 108 may have a different thickness. The first spin-polarizing layer structure 108 may have a thickness ranging from about 0.2 nm to about 3 nm.

The second spin-polarizing layer structure 110 has one or more layers. The one or more layers of the second spin-polarizing layer structure 110 may be arranged in a stack. Each layer of the second spin-polarizing layer structure 110 may include but is not limited to cobalt iron boron (CoFeB), cobalt, iron and cobalt iron. Each layer of second spin-polarizing layer structure 110 may have a different thickness. The second spin-polarizing layer structure 110 may have a thickness ranging from about 0.2 nm to about 3 nm.

The first spin-polarizing layer structure 108 and the second spin-polarizing layer structure 110 may be disposed adjacent to the spacer layer 106 in order to achieve higher magnetoresistance (MR). The thicknesses of the first spin-polarizing layer structure 108 and the second spin-polarizing layer structure 110 may be varied between about 0.2 nm and about 3 nm to increase the magnetoresistance value. A larger thickness for the first spin-polarizing layer structure 108 and the second spin-polarizing layer structure 110 is desirable to prevent the transfer of fcc (111) texture from the soft magnetic layer 104 to the spacer layer 106 or from the seed layer (details of which will be described later) to the spacer layer 106 as the spacer layer 106 exhibits desired properties in the body centered (bcc) (200) texture.

The magnetoresistance device 100 may include a seed layer structure 112. The seed layer structure 112 may be arranged such that the soft magnetic layer 104 is disposed between the seed layer structure 112 and the first spin-polarizing layer structure 108. The seed layer structure 112 may include at least one layer. The at least one layer of the seed layer structure 112 may include a material or a combination of materials selected from a group of materials consisting of tantalum, chromium, titanium, nickel, tungsten, ruthenium, palladium, platinum, zirconium, hafnium, silver, gold, aluminum, antimony, molybdenum, tellurium, cobalt iron, cobalt iron boron and cobalt chromium. The at least one layer of the seed layer structure 112 may have a thickness ranging from about 0 nm to about 7 nm. In other words, the seed layer structure 112 may have a thickness ranging from about 0 nm to about 7 nm.

In one embodiment, the at least one layer of the seed layer structure 112 may be a conductive electrode 114. When the at least one layer of the seed layer structure 112 is used as the electrode 114, the at least one layer of the seed layer structure 112 may have a thickness greater than 7 nm.

The number of layers of the seed layer structure 112 can vary for different embodiments. In one embodiment, the capping layer structure 112 may include only one layer 113. The layer 113 may include palladium. The layer 113 may have a thickness of about 50 Å.

In another embodiment (e.g. as illustrated in FIG. 1), the seed layer structure 112 may include a first layer 113 and a second layer 115. The first layer 113 may be disposed between the soft magnetic layer 104 and the second layer 115. The first layer 113 may include palladium. The second layer 115 may include tantalum. The second layer 115 can be used as an adhesion layer to a substrate 120. The second layer 115 may have a thickness of about 50 Å.

The seed layer structure 112 may provide a hexagonal close packing (hcp) (002) texture, a face-centered (fcc) (111) texture or a body centered (bcc) (200) texture. The seed layer structure 112 may help the soft magnetic layer 104 (e.g. the stacks 202 of the soft magnetic layer 104) to grow in fcc (111) orientation and thus, achieving perpendicular magnetic anisotropy (PMA) in the stacks 202. A seed layer structure 112 with a smaller thickness is desirable for having a more coherent tunneling through the spacer layer 106. Perpendicular magnetic anisotropy (PMA) may be achieved in the soft magnetic layer 104 with a minimum thickness of about 30 Å for the seed layer structure 112.

The magnetoresistance device 100 may further include a capping layer structure 116. The capping layer structure 116 may be arranged such that the hard magnetic layer 102 is disposed between the capping layer structure 116 and the second spin-polarizing layer structure 110. The capping layer structure 116 may be part of the electrode 114.

The capping layer structure 116 may include at least one layer. The at least one layer of the capping layer structure 116 may include a material or a combination of materials selected from a group of materials consisting of tantalum, chromium, titanium, nickel, tungsten, ruthenium, palladium, platinum, zirconium, hafnium, silver, gold, aluminum, antimony, molybdenum, tellurium and cobalt chromium. In one embodiment, the capping layer structure 116 may have a thickness ranging between about 30 Å and about 150 Å.

The number of layers of the capping layer structure 116 can vary for different embodiments. In one embodiment, the capping layer structure 116 may include only one layer 117. The layer 117 may include palladium. The layer 117 may have a thickness of about 50 Å.

In another embodiment (e.g. as illustrated in FIG. 1), the capping layer structure 116 may include a first layer 117 and a second layer 118. The first layer 117 may be disposed between the hard magnetic layer 102 and the second layer 108. The first layer 117 may include palladium. The second layer 118 may include tantalum or ruthenium. The second layer 118 can be used to avoid oxidation. The first layer 117 may have a thickness of about 50 Å. The second layer 118 may have a thickness of about 50 Å.

In one embodiment, the substrate 120 may be disposed adjacent the seed layer structure 112 (e.g. the second layer 115 of the seed layer structure 112). In one embodiment, the substrate 120 includes but is not limited to silicon dioxide, silicon, silicon nitride, magnesium oxide and glass.

In one embodiment, the magnetoresistance device 100 has the hard magnetic layer 102 arranged above the spacer layer 106 and the soft magnetic layer 104 arranged below the spacer layer 106.

In another embodiment, the magnetoresistance device 100 may have the hard magnetic layer 102 arranged below the spacer layer 106 and the soft magnetic layer 104 arranged above the spacer layer 106.

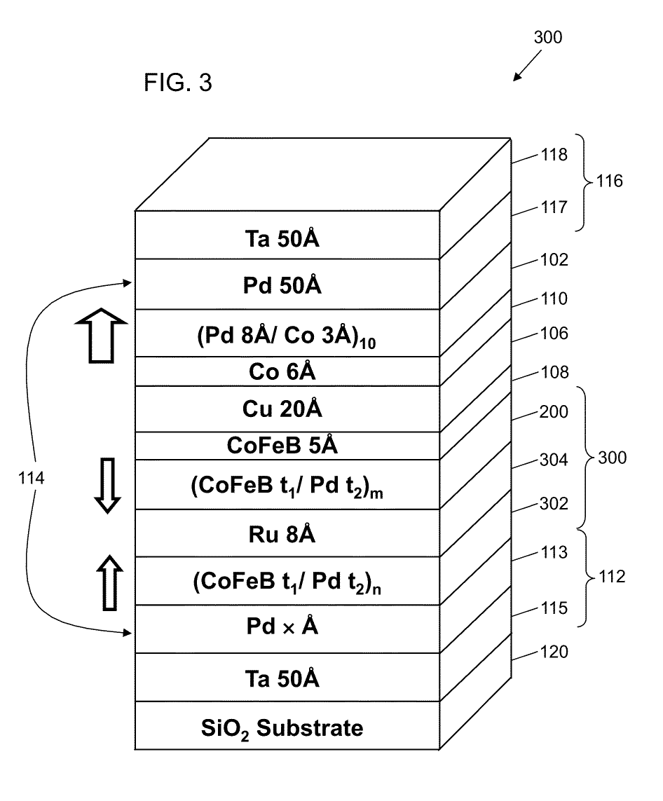

FIG. 3 shows a three-dimensional view of a magnetoresistance device 300 according to one embodiment. The magnetoresistance device 300 is similar to the magnetoresistance device 100 except that the soft magnetic layer 104 includes a further multi-layer structure 302. The further multi-layer structure 302 has identical or similar structure and materials as the multi-layer structure 200. At least one of the multi-layer structure 200 and the further multi-layer structure 302 is made of CoFeB/X, where X is platinum or palladium. The multi-layer structure 200 and the further multi-layer structure 302 are coupled antiferromagnetically to each other. The antiferromagnetic coupling between the multi-layer structure 200 and the further multi-layer structure 302 are obtained through the use of thin layers 304. The thin layers 304 may include but are not limited to ruthenium, rhodium, and an alloy of ruthenium and rhodium.

The thicknesses of the various layers of the magnetoresistance device 300 can be adjusted such that the magnetoresistance device 300 has a desirable magnetoresistance. The total number of stacks 202 (e.g. total number of the first layer 204 and the second layer 206) in the magnetoresistance device 300 can be higher than the total number of stacks 202 in the magnetoresistance device 100. Perpendicular magnetic anisotropy (PMA) can be achieved with improved thermal stability.

In short, the magnetoresistance device 300 can have a dual Magnetic Tunneling Junction (MTJ) with two soft magnetic layers (e.g. 200, 302) made of at least one multilayer of (CoFeB/X) where X is Pt or Pd. The magnetoresistance device 300 use e.g. CoFeB/Pd multilayers as the soft magnetic layer to achieve lower switching current as well as high thermal stability which can allow a decrease of the design structure size to 40 nm and consequently, achieving higher storage.

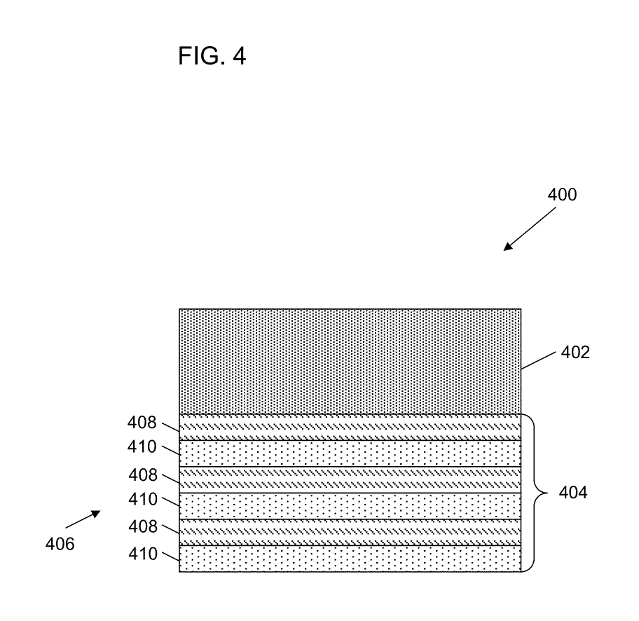

FIG. 4 shows a schematic diagram of a magnetoresistance device 400 according to one embodiment. The magnetoresistance device 400 includes a hard magnetic layer 402 and a soft magnetic layer 404. The soft magnetic layer 404 has a multi-layer stack structure 406. The multi-layer stack structure 406 may have at least one first layer 408 of a first material and at least one second layer 410 of a second material. For illustration purposes, the multi-layer stack structure 406 has three first layers 408 of the first material and three second layers 410 of the second material. The three first layers 408 of the first material and the three second layers 410 of the second material are arranged in an alternating arrangement.

In one embodiment, the first material may include a cobalt based magnetic material. The cobalt based magnetic material may have a formula Co—X—Y. X may include iron, and Y may include boron or boron nitride.

The first material may be cobalt-iron-boron nitride (CoFeBN). CoFeBN is a soft magnetic material which can provide a low switching current.

In one embodiment, the second material may include platinum, palladium or nickel. Nickel is a magnetic material. By using nickel for the second material, a higher spin-polarization and magnetoresistance can be achieved.

The magnetoresistance devices 100, 300, 400 described above can have a low switching current that can be used in spin-transfer torque magnetic random access memory (STT-MRAM). In MRAM applications, the magnetoresistance devices 100, 300, 400 may be part of a memory circuit, along with transistors that provide the read and write currents. The magnetoresistance devices 100, 300, 400 can work as or can be part of a multi-level MRAM. The magnetoresistance devices 100, 300, 400 can also be applicable to read-sensors of hard disk drives and magnetic field sensors.

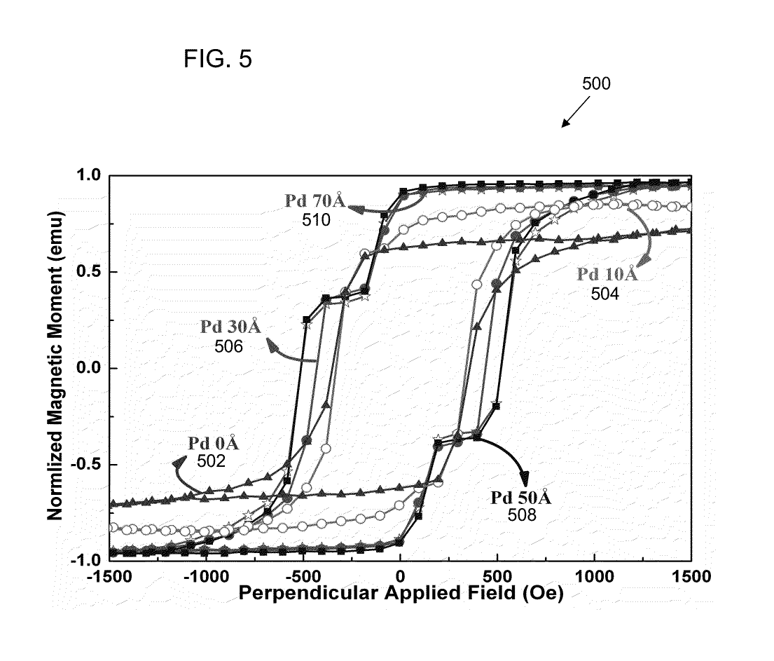

FIG. 5 shows a graph 500 illustrating a hysteresis loop of the magnetoresistance device 100 for different thicknesses of the seed layer structure 112. In one embodiment, the seed layer structure 112 may include palladium. The soft magnetic layer 104 may include a CoFeB/Pd multi-layer structure.

Plot 502 shows normalized magnetic moment plotted against perpendicular applied field for a seed layer structure having a thickness of 0 Å (0 nm). Plot 504 shows normalized magnetic moment plotted against perpendicular applied field for a seed layer structure having a thickness of 10 Å (1 nm). Plot 506 shows normalized magnetic moment plotted against perpendicular applied field for a seed layer structure having a thickness of 30 Å (3 nm). Plot 508 shows normalized magnetic moment plotted against perpendicular applied field for a seed layer structure having a thickness of 50 Å (5 nm). Plot 510 shows normalized magnetic moment plotted against perpendicular applied field for a seed layer structure having a thickness of 70 Å (7 nm).

It can be observed from graph 500 that the hard magnetic layer 102 and the soft magnetic layer 104 switch at different fields. Using CoFeB/Pd for the soft magnetic layer 104, can achieve the switching of the hard magnetic layer 102 and the soft magnetic layer 104 at different fields. It can also be observed that there is a larger difference between the switching fields of the hard magnetic layer 102 and the soft magnetic layer 104 for the seed layer structure 112 having a thickness of 30 Å (3 nm) and above. Therefore, a thickness of 30 Å (3 nm) and above is preferred for the seed layer structure 112 due to the distinct switching between the hard magnetic layer 102 and the soft magnetic layer 104.

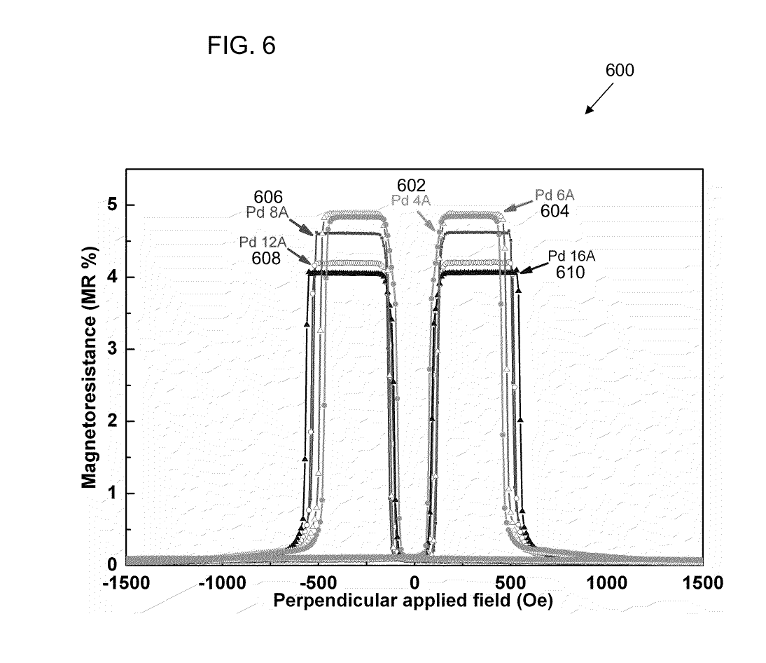

FIG. 6 shows a graph 600 illustrating a magnetoresistance (MR) behavior of the magnetoresistance device 100 for different thicknesses of the seed layer structure 112. In one embodiment, the seed layer structure 112 may include palladium. The soft magnetic layer 104 may include a CoFeB/Pd multi-layer structure. Electric current flows in the film plane, i.e. current-in-plane (CIP) configuration.

Plot 602 shows magnetoresistance plotted against perpendicular applied field for a seed layer structure having a thickness of 4 Å (0.4 nm). Plot 604 shows magnetoresistance plotted against perpendicular applied field for a seed layer structure having a thickness of 6 Å (0.6 nm). Plot 606 shows magnetoresistance plotted against perpendicular applied field for a seed layer structure having a thickness of 8 Å (0.8 nm). Plot 608 shows magnetoresistance plotted against perpendicular applied field for a seed layer structure having a thickness of 12 Å (1.2 nm). Plot 610 shows magnetoresistance plotted against perpendicular applied field for a seed layer structure having a thickness of 16 Å (1.6 nm).

The thickness of the seed layer structure 112 can be chosen to achieve optimized values of perpendicular magnetic anisotropy and a high magnetoresistance (MR). Too large values of the thickness of the seed layer structure 112 may result in a reduced tunneling magnetoresistance (TMR) as the soft magnetic layer 104 (which may be formed with fcc (111) texture) may affect the formation of the spacer layer 106 (e.g. magnesium oxide (MgO) bcc (200) tunnel barrier). Consequently, this may result in a lower magnetoresistance (MR). On the other hand, the seed layer structure 112 having a too thin layer may not be helpful to promote perpendicular magnetic anisotropy. As shown in FIG. 6, the seed layer structure 112 having a thickness of about 0.4 nm to about 0.6 nm shows the highest MR value (see plot 602 and plot 604).

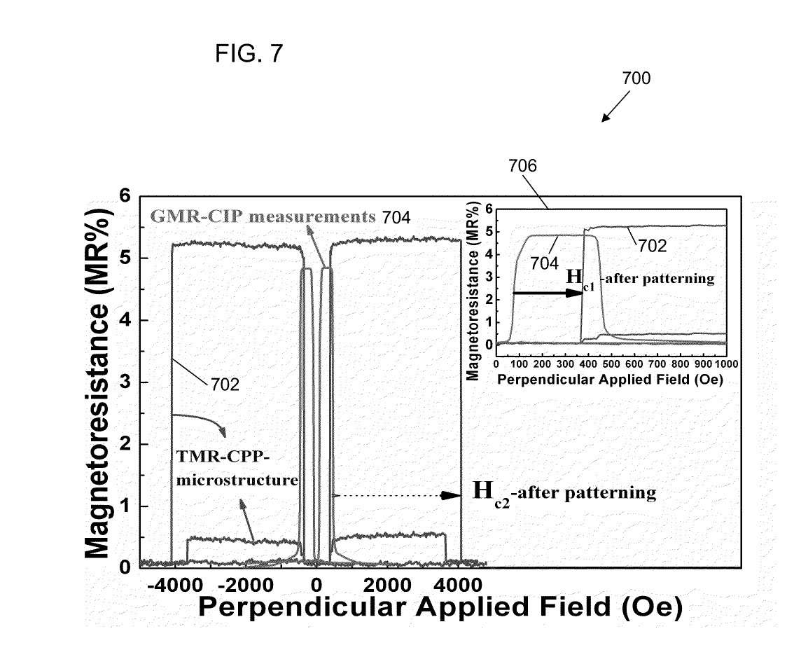

FIG. 7 shows a graph 700 illustrating a magnetoresistance (MR) behavior of the magnetoresistance device 100. In one embodiment, the soft magnetic layer 104 may include a CoFeB/Pd multi-layer structure. The hard magnetic layer 102 may include a Co/Pd multi-layer structure. The spacer layer 106 may include MgO. The first spin-polarizing layer structure 108 and the second spin-polarizing layer structure 110 may include CoFeB. The seed layer structure 112 may include palladium. Electric current may flow perpendicular to the film plane, i.e. current-perpendicular-to-plane (CPP) configuration.

Plot 702 shows magnetoresistance plotted against perpendicular applied field for CPP configuration of the magnetoresistance device 100 (after patterning). Plot 704 shows magnetoresistance plotted against perpendicular applied field for CIP configuration of the magnetoresistance device 100 (before patterning). The inset 706 shows a magnified graph 700 of the plot 702 and the plot 704 from 0 Oe to 1000 Oe of the perpendicular applied field. It can be observed from graph 700 that the switching fields of the hard magnetic layer 102 and the soft magnetic layer 104 increase after patterning.

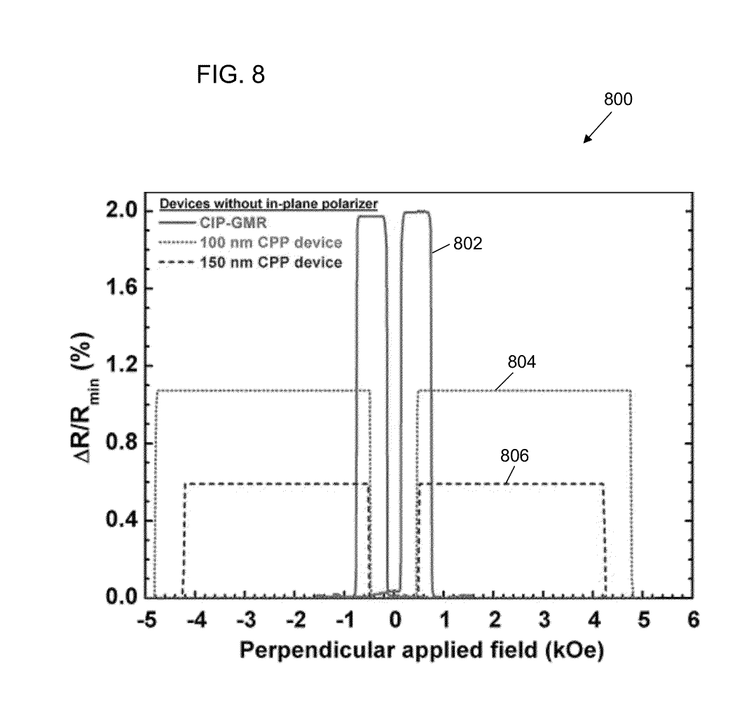

Switching fields of materials used in conventional devices also increase after patterning. FIG. 8 shows a plot 802 of CIP-giant magnetoresistance (GMR) of a conventional single spin valve (SSV) unpatterned thin film, a plot 804 of CPP-GMR of 100 nm diameter device pillar and a plot 806 of CPP-GMR of 150 nm diameter device pillar. It can be observed that the switching field of Co/Pd multilayer increases from about a few hundred Oe before patterning to 4-5 kOe after patterning. This indicates that the Co/Pd multilayer is suitable to be used for a hard magnetic layer. However, if the Co/Pd multilayer is used for a soft magnetic layer, its coercivity will increase. As such, a higher switching current may be required for the Co/Pd multilayer.

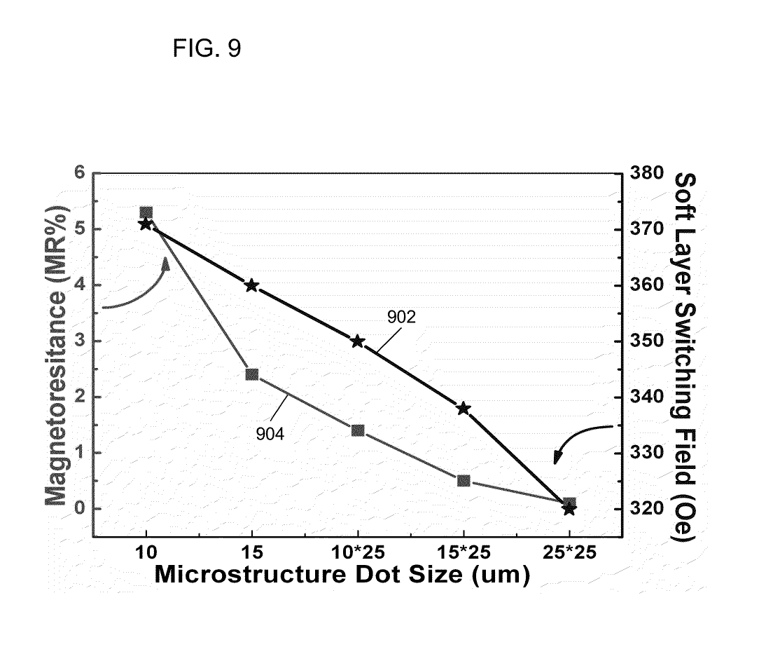

FIG. 9 shows a plot 902 of a switching field of a soft magnetic layer 104 of the magnetoresistance device 100 plotted against a size of the magnetoresistance device 100. FIG. 9 also shows a plot 904 of magnetoresistance of the magnetoresistance device 100 plotted against the size of the magnetoresistance device 100. In one embodiment, the soft magnetic layer 104 may include a CoFeB/Pd multi-layer structure. The CoFeB composition of the soft magnetic layer 104 may be Co₂₀Fe₆₀B₂₀. The CoFeB layer of the soft magnetic layer 104 may have a thickness of about 3 Å. The Pd layer of the soft magnetic layer 104 may have a thickness of about 6 Å. The soft magnetic layer 104 may have three stacks of the CoFeB layer and the Pd layer. The hard magnetic layer 102 may include a Co/Pd multi-layer structure. The spacer layer 106 may include MgO. The first spin-polarizing layer structure 108 and the second spin-polarizing layer structure 110 may include CoFeB. The seed layer structure 112 may include palladium. The seed layer structure 112 may have a thickness of about 30 Å.

It can be observed that the switching field of the soft magnetic layer 104 does not increase significantly when the size of the magnetoresistance device 100 decreases. It can also be observed that the magnetoresistance of the magnetoresistance device 100 increases when the size of the magnetoresistance device 100 decreases.

Therefore, using CoFeB/Pd multi-layer structure for the soft magnetic layer 104 can allow scaling down of the dimensions of the magnetoresistance device 100. The reduction in the dimensions of the magnetoresistance device 100 can achieve higher magnetoresistance.

Thus, the magnetoresistance devices described above can provide a reduced size, a low switching current, a high thermal stability and a higher storage density.

While the preferred embodiments of the devices and methods have been described in reference to the environment in which they were developed, they are merely illustrative of the principles of the inventions. Other embodiments and configurations may be devised without departing from the spirit of the inventions and the scope of the appended claims.

We claim:

1. A magnetoresistance device, comprising:
a hard magnetic layer;
a soft magnetic layer comprising a multi-layer stack structure;
wherein the multi-layer stack structure has a first layer of a first material and a second layer of a second material;
wherein the first material comprises cobalt iron boron and the second material comprises palladium or platinum.

2. The magnetoresistance device of claim 1,
wherein the multi-layer stack structure comprises one or more stacks;
wherein each stack has a first layer of the first material and a second layer of the second material.

3. The magnetoresistance device of claim 2, wherein the number of stacks of the multi-layer stack structure ranges from 2 to 20.

4. The magnetoresistance device of claim 1, wherein the hard magnetic layer comprises any one of a group consisting of cobalt platinum, iron platinum, and a multi-layer stack structure having a first layer of cobalt and a second layer of material comprising a material or a combination of materials selected from a group of materials consisting of platinum, palladium, iron palladium and nickel.

5. The magnetoresistance device of claim 1, further comprising a spacer layer disposed between the hard magnetic layer and the soft magnetic layer.

6. The magnetoresistance device of claim 5, wherein the spacer layer comprises any one of a group consisting of magnesium oxide, stack of magnesium and magnesium oxide, copper and aluminum oxide (AlₓO_{y}).

7. The magnetoresistance device of claim 5, further comprising:
a first spin-polarizing layer structure disposed between the spacer layer and the soft magnetic layer; and
a second spin-polarizing layer structure disposed between the spacer layer and the hard magnetic layer.

8. The magnetoresistance device of claim 7,
wherein the first spin-polarizing layer structure comprises one or more layers, each layer having a different thickness;
wherein each layer of the first spin-polarizing layer structure comprises any one of a group consisting of cobalt iron boron, iron, cobalt and cobalt iron;
wherein the second spin-polarizing layer structure comprises one or more layers, each layer having a different thickness;
wherein each layer of the second spin-polarizing layer structure comprises any one of a group consisting of cobalt iron boron, cobalt, iron and cobalt iron.

9. The magnetoresistance device of claim 7,
further comprising a seed layer structure;
wherein the soft magnetic layer is disposed between the seed layer structure and the first spin-polarizing layer structure.

10. The magnetoresistance device of claim 9,
wherein the seed layer structure comprises at least one layer;
wherein the at least one layer of the seed layer structure comprises a material or a combination of materials selected from a group of materials consisting of tantalum, chromium, titanium, nickel, tungsten, ruthenium, palladium, platinum, zirconium, hafnium, silver, gold, aluminum, antimony, molybdenum, tellurium, cobalt iron, cobalt iron boron and cobalt chromium.

11. The magnetoresistance device of claim 10, wherein the at least one layer of the seed layer structure is a conductive electrode.

12. The magnetoresistance device of statement 11, wherein the at least one layer of the seed layer structure, when used as the electrode, has a thickness greater than 7 nm.

13. The magnetoresistance device of claim 11,
further comprising a capping layer structure;
wherein the hard magnetic layer is disposed between the capping layer structure and the second spin-polarizing layer structure.

14. The magnetoresistance device of claim 13, wherein the capping layer structure is part of the electrode.

15. The magnetoresistance device of claim 14,
wherein the capping layer structure comprises at least one layer,
wherein the at least one layer of the capping layer structure comprises a material or a combination of materials selected from a group of materials consisting of tantalum, chromium, titanium, nickel, tungsten, ruthenium, palladium, platinum, zirconium, hafnium, silver, gold, aluminum, antimony, molybdenum, tellurium and cobalt chromium.

16. The magnetoresistance device of claim 1,
wherein the soft magnetic layer further comprises a further multi-layer structure;
wherein the multi-layer structure and the further multi-layer structure are coupled antiferromagnetically to each other.

17. The magnetoresistance device of claim 16, wherein the antiferromagnetic coupling between the multi-layer structure and the further multi-layer structure are obtained through the use of thin layers of one or more materials selected from a group consisting of ruthenium, rhodium, and an alloy of ruthenium and rhodium.

18. A magnetoresistance device, comprising:
a hard magnetic layer;
a soft magnetic layer comprising a multi-layer stack structure;
wherein the multi-layer stack structure has a first layer of a first material and a second layer of a second material;
wherein the first material comprises a cobalt based magnetic material.

19. The magnetoresistance device of claim 18,
wherein the cobalt based magnetic material has a formula Co—X—Y;
wherein X comprises iron and Y comprises boron or boron nitride.

20. The magnetoresistance device of claim 18, wherein the second material comprises any one of a group consisting of platinum, palladium and nickel.
